(19) United States
(12) Patent Application Publication
(10) Pub. No.: US 2010/0219892 A1
(43) Pub. Date: Sep. 2, 2010

(54) CURRENT LIMITER CIRCUIT

(75) Inventor: Guillaume De Cremoux, Edinburgh (GB)

Correspondence Address: Docket Clerk, P.O. Box 802432, Dallas, TX, 75380, US

(73) Assignee: NXP B.V., Eindhoven (NL)

(21) Appl. No.: 12/063,465

(22) PCT Filed: Jul. 17, 2006
(86) PCT No.: PCT/IB2006/052435

§ 371 Date: May 18, 2010

(30) Foreign Application Priority Data
Aug. 17, 2005 (EP) 05107543.0

(51) Int. Cl. H03F 3/16

(52) U.S. Cl. 330/288

(57) ABSTRACT

The present invention relates to a circuit configuration for detecting and rapidly limiting large current increase based on high current injection at the output terminal (out). In particular, a gate-controlled switching device (PO), controlled by a driver circuit (40) through a low resistive element (RO) and passed through by a current overshoot, will be alternatively driven by the circuit of the present invention while having its control terminal charged by the high injected current. Thus, when large voltage increase generated by a steep front impulse with a positive slope is detected by the capacitor (C) and transmitted to the gate terminal (GateN), the circuit of the present invention bypasses the driver circuit (40) while injecting a significant current peak issued from the transistor (P3) towards the gate terminal (GateP) of the gate-controlled switching device (PO), whereas the capacitor (C) is discharging very slowly through the gate terminal (GateN). The current amplification leading to the injected current peak is made through the use of the current mirror (P4, P3) with a large current mirror ratio and enhanced by the presence of the diodes (DO, D1). In a quiescent mode or when large voltage decrease generated by a steep front impulse with a negative slope is detected by the capacitor (C) and transmitted to the gate terminal (GateN), the transistor (P4) becomes short-circuited by the current source (CS3) sourcing the current flowing through the diode (D1), such that the current mirror (P4+P5, P3) is virtually replaced by the current mirror (P5, P3) with a much lower current mirror ratio. As a result, the low current of the sinking current source (CS2) will be sufficient to sink the lower current mirrored by the current mirror (P3, P5) and will then allow the driver circuit (40) to take over the control of the switching device (PO). Finally, this circuit configuration operates unidirectionally while limiting large current increase but not large current decrease through the gate-controlled switching device (PO).

The present invention relates to a current limiter circuit, and more particularly to a very high speed circuit able to sense and limit excessive current overshoots based on high current injection to a control terminal of a switching device. This circuit will be unidirectional while limiting current increase but not current decrease.

Portable and mobile devices, such as the cellular phone, personal digital assistant (PDA), portable personal computer, camcorder, digital camera or MP3 player for example, need to be electrically supplied by an operational battery whenever no alternative electric power source is made available. The circuit used for such an operation mode consists of a controllable switching device separating the battery from the device and exhibiting a low resistance R within a range of 0.1 to 0.5Ω for example. Since this circuit can also serve as a battery charging circuit, it is therefore possible at any time to connect a DC power source, such as a wall plug adapter, at the same terminal as the device being supplied by the battery. At this instant, the controllable switching device will be still in low ohmic mode such that the voltage gap existing between the DC power source (e.g. 6 V) and the battery (e.g. 3.6 V) will result in current overshoot (e.g. typically ˜5 A: (6 V−3.6 V)/0.5Ω or even much more) flowing through the controllable switching device towards the battery. Although the controllable switching device is usually controlled by a driver circuit able to minimize this current (e.g. to 1 A), this limitation is nevertheless based on a slow process of current regulation which takes typically several microseconds shared among the time needed to detect the current overshoot and the time needed to charge and hence turn off the controllable switching device. Moreover, the transition from the reverse mode, when the battery supplies a device, to the forward mode, when the wall plug adapter charges the battery, happens typically with a slope of 5 V/μs corresponding to the time constant of the wall plug adapter connection. Hence, the solution consisting in reducing in time these overshoots proves technically impossible, whereas these time-limited current overshoots can jeopardize the battery normal behavior and decrease the battery lifetime.

It is therefore an object of the present invention to provide a current limiter circuit configuration for a battery charging circuit in order to very rapidly detect and limit any current variation through a gate-controlled switching device. For improving security, the current limiter circuit will be made unidirectional while being configured to limit current increase but not current decrease.

The object is achieved by a variable current amplifier circuit configuration as claimed in claim 1, a current limiter circuit configuration as claimed in claim 13, a battery charging circuit configuration as claimed in claim 17 and a method as claimed in claim 18.

Accordingly, a current limiter circuit comprises a variable current amplifier circuit and a gate-controlled switching means controlled by a driver means through a resistive element with a low resistance. The output of the variable current amplifier circuit is connected to the control terminal of the gate-controlled switching means and thereby allows the variable current amplifier circuit to control the latter. Due to the resistive element, this control will be effective for high current injection at the output of the variable current amplifier circuit.

Furthermore, the variable current amplifier circuit includes at its input terminal a detection stage comprising a capacitive element for thus rapidly detecting and transmitting voltage variation that corresponds to a current variation, followed by a regulation stage for regulating to quiescent values the bias voltage of a transistor submitted to the variation as well as the current controlled by the bias voltage, and a variable amplification stage based on a variable load of current mirrors owning different current mirror ratios for thereby injecting high current to the control terminal of the gate-controlled switching means only when a voltage increase is detected. The gate of the transistor is connected to the output terminal of the detection stage which thereby discharges very slowly and thus enables the driver means to have time enough before controlling the current through the gate-controlled switching means. The current to be processed by the variable amplification stage can be exponentially increased while passing through a diode in series with a protection resistor. The current to be injected by the variable amplification stage will be hence much higher and will result in a much shorter time to charge the control terminal and switch off the gate-controlled switching means.

Moreover, the variable current amplifier circuit has a sinking current source connected at its output, which sinks the amplified current, which is not injected to the control terminal of the gate-controlled switching means. Its current sinking capability is poor and thus allows to not overriding the action of the driver means. Thereby, the current limiter circuit operates unidirectional for meeting higher security requirements while limiting increase current but not decrease current.

Additionally, the current limiter circuit can be coupled to a battery charging circuit for thus limiting any current overshoot flowing through the gate-controlled switching means from the power supply means towards the battery.

Further advantageous embodiments are defined in the dependent claims.

The present invention will be now described based on preferred embodiments with reference to the accompanying drawings in which:

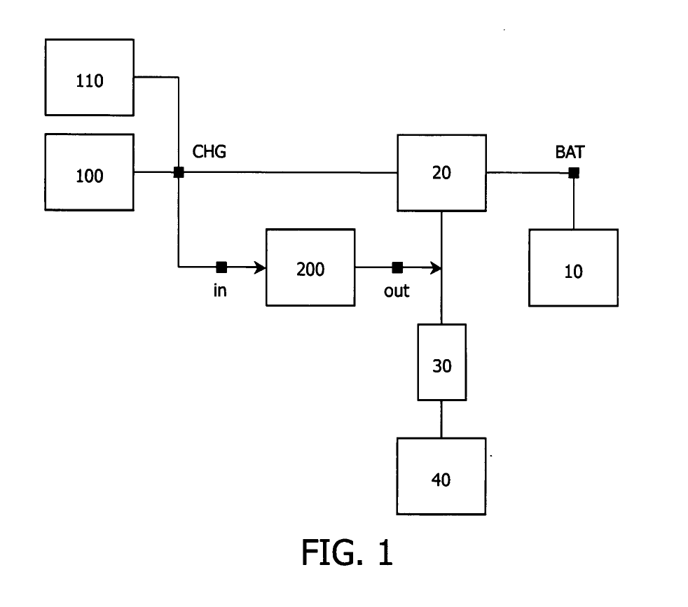

FIG. 1 shows a schematic block diagram of a battery charging circuit in a charge-and-play mode coupled to a current limiter circuit according to the principle of the invention;

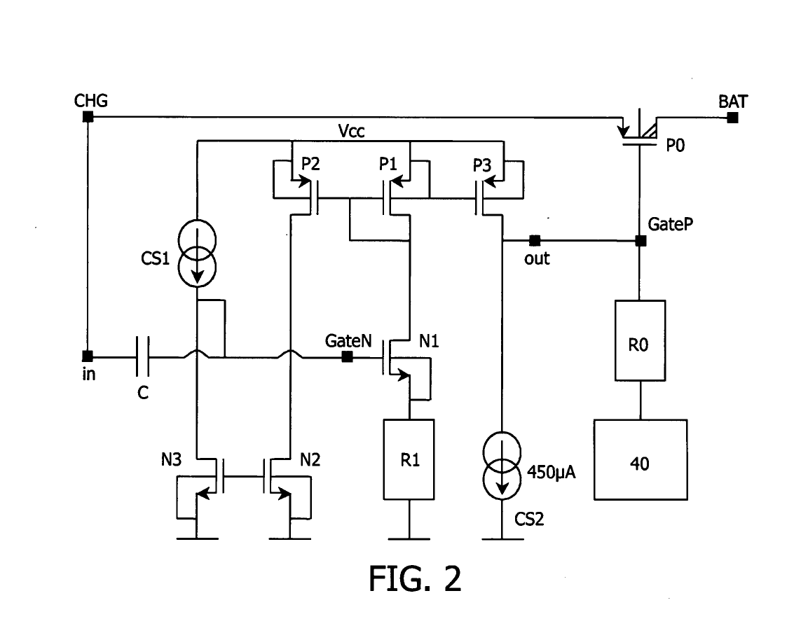

FIG. 2 shows a current limiter circuit boosting a linear current through a constant load;

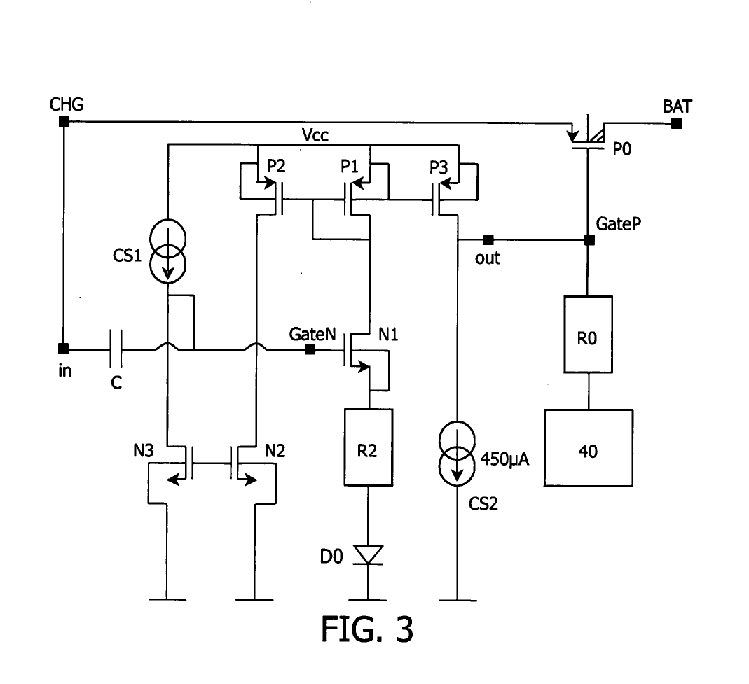

FIG. 3 shows a current limiter circuit boosting a non-linear current through a constant load;

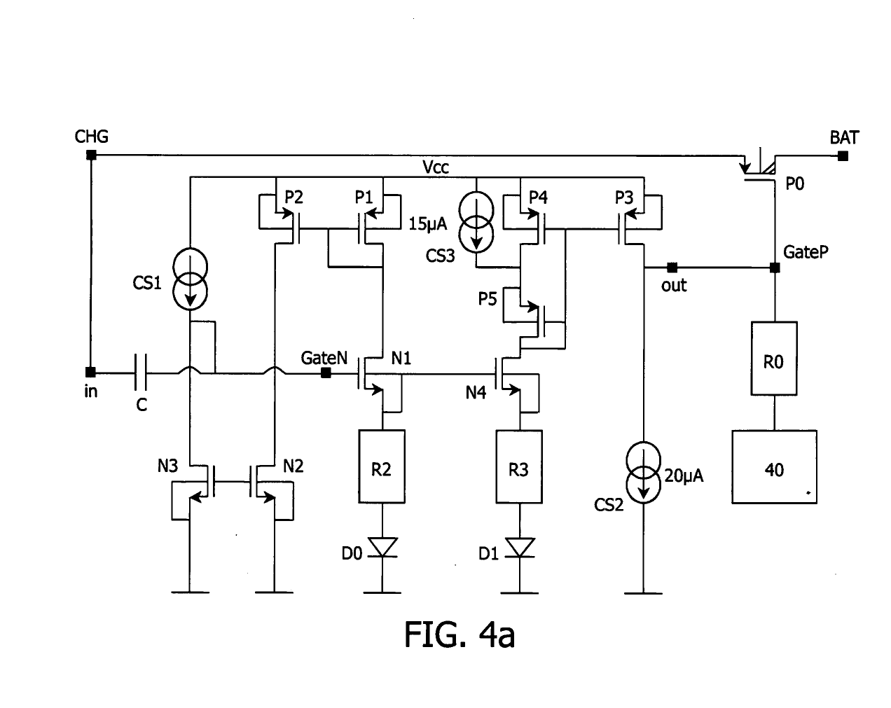

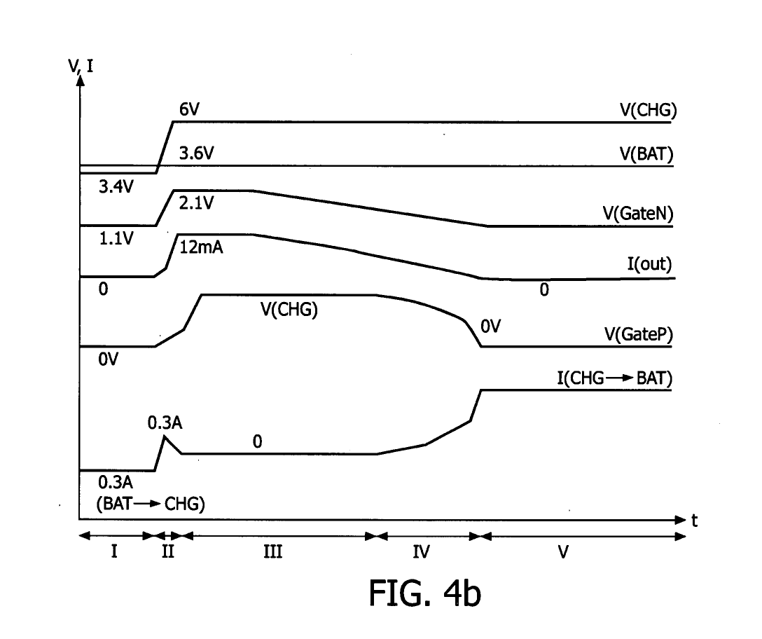

FIG. 4a shows a current limiter circuit boosting a non-linear current through a variable load according to the first preferred embodiment of the invention;

FIG. 4b shows the simulation results for a current overshoot of 0.3 A during 200 ns (refer to time period II) with a 20 μA sinking current source according to the first preferred embodiment of the invention.

In the following, a schematic block diagram of a battery charging circuit in a charge-and-play mode coupled to a current limiter circuit, a current limiter circuit boosting a linear current through a constant load and a current limiter circuit boosting a non-linear current through a constant load, such as depicted in FIGS. 1, 2 and 3 respectively, will be first introduced in order to better describing the first preferred embodiment, such as depicted in FIGS. 4a and 4b.

In FIG. 1, a battery charging circuit, coupled via the terminals in and out to a variable current amplifier circuit 200, includes a terminal CHG to which a DC power source 100 and an accessory 110 can be connected, a terminal BAT to which a battery 10 can be connected, and a gate-controlled switching device 20 coupled between both terminals and controlled by a driver circuit 40 through a resistive element 30 with a resistance R0 low enough for not disturbing the action of the driver circuit 40. The accessory 110 can be an USB plug which is connected to the terminal CHG for being supplied by the battery 10. While staying connected, the DC power source 100 can also share the same terminal CHG for charging the battery 10, thereby generating a current overshoot from the terminal CHG towards the terminal BAT.

FIG. 2 depicts a current limiter circuit wherein the gate-controlled switching device PO and the resistive element 30 correspond to the blocks 20 and 30 of FIG. 1. The variable current amplifier circuit 200 comprises schematically three stages for the detection, regulation and amplification. The detection stage will enable the capacitor C to detect any voltage variation before transmitting it to the gate terminal GateN of the N-channel transistor N1 which controls a first current (e.g. 10 μA), such that any voltage variation will result in a current variation of the first current. The regulation stage allows the bias voltage at the gate terminal GateN to be regulated to a value in quiescent mode. Thus, the first current will be mirrored firstly by a two P-channel transistor current mirror P1, P2, with a current mirror ratio (e.g. 0.1) determined by the aspect ratio (W/L, where W and L are channel width and length, respectively) of each transistor in the current mirror, and secondly by a two N-channel transistor current mirror N2, N3, with, for example, a same current mirror ratio (e.g. 0.1). The mirrored first current (e.g. 10 μA×0.1×0.1=0.1 μA) will be then compared to the reference current (e.g. 100 nA) sourced by the current source CS1. The comparison result will then regulate the gate voltage GateN and the current through N1.

The amplification stage amplifies the first current through a current mirror with an aspect ratio greater than 1. The first current is mirrored by the P-channel transistors current mirror P1, P3 having a large current mirror ratio e.g. 40 for enhancing the amplification of the first current e.g. 10 μA×40=400 μA.

In quiescent mode, the amplified first current e.g. 400 μA mirrored by the two P-channel transistors current mirror P1, P3 will be not sufficient for compensating the sinking current e.g. 450 μA of the current source CS2, such that the branch GateP, out will be sunk by a low current e.g. 50 μA enhancing the conduction mode of the gate-controlled switching device P0. When a positive voltage variation dV/dt is detected by the capacitor C after the DC power source 100 of FIG. 1 has been connected to the terminal CHG, the bias voltage at the gate terminal GateN is suddenly pulled up by the rising voltage V(CHG), whereas the gate-controlled switching device P0 which behaves as a resistor with a low resistance is suddenly passed through by a current overshoot. The positive variation will be then transmitted by the bias voltage to the first current, which will rise e.g. from 10 μA up to 25 μA, before being amplified by the P-channel transistor current mirror P1, P3 with a large current mirror ratio e.g. 40. The resulting current will become a high current peak e.g. 25 μA×40=1000 μA, which will exceed the sinking current capability of the current source CS2 e.g. 450 μA. The excess current peak will be injected through the output terminal out and will be so high that the resistive element R0 will behave as an open-circuit. Thus, the gate terminal GateP will be charged by this excess current while stopping the current increase through the gate-controlled switching device P0.

Since the time taken for discharging the capacitor C is long due to its dependence on the high resistance of the gate terminal GateN, the first current driven by the bias voltage will slowly return to its quiescent value (e.g. 10 μA). Through the P-channel transistor current mirror (P1, P3), the mirrored first current will revert to its quiescent value e.g. 400 μA and will be again overruled by the current source CS2 e.g. 450 μA. Thus, a low sinking current e.g. 50 μA will circulate again from the terminal GateP towards the output terminal out, while slowly discharging the gate of the gate-controlled switching device P0 at the gate terminal GateP. It will result that the current, which flows through it will slowly increase too. This slowness enables the driver circuit 40 to get time enough for taking over the current limitation. However, when a negative voltage variation dV/dt is detected by the capacitor C, the bias voltage at the gate terminal GateN is suddenly pulled down by the decreasing voltage V(CHG) and leads to a decrease of the first current. Despite the amplification stage, the sinking current capability of the current source CS2 e.g. 450 μA will be sufficiently important so as to keep discharged the gate of the gate-controlled switching device P0 at the gate terminal GateP and to enhance the conduction mode, overriding by the same the action of the driver circuit 40 unable to switch off the gate-controlled switching device P0.

Such a current limiter circuit boosting a linear current, first current passing through R1 through a constant load i.e. current mirror P1, P3 has several drawbacks: a large current consumption e.g. 400 μA in the last transistor P3 in quiescent mode, a limited current injection rate e.g. a current peak from 500 μA to 1 mA, which charges quite slowly the gate of the gate-controlled switching device P0, and its capacity to not limit current decrease that it is important for security reasons to limit by rapidly deactivating the gate-controlled switching device P0. Finally, a current overshoot of 3 A can be obtained during 1 μs with this circuit.

This circuit can be improved as shown in FIG. 3, wherein the resistive element R1 e.g. 100 kΩ that grounds the source of the transistor N1 is now replaced by a non-linear resistance such as the diode D0 which will be protected from blowing up by a series resistive element R2 e.g. 10 kΩ. The FIG. 3 thus depicts a current limiter circuit boosting a non-linear current through a constant load. When a positive voltage variation dV/dt is detected by the capacitor C, the bias voltage at the gate terminal GateN is suddenly pulled up by the rising voltage V(CHG). Connected to the bias voltage, the source potential increases as well while exponentially increasing the first current that flows through the diode D0. Limited by the resistive element R2, the current increase can thus reach 100 μA and lead to a current peak of 4 mA outputting from the amplification stage and speeding up the charge of the gate of the gate-controlled switching device P0. With this improvement, the current overshoot can be reduced to 0.8 A during 1 μs before the current increase is stopped and return to 0. Then, the current through the gate-controlled switching device PO will increase slowly. Nevertheless, this circuit still exhibits two drawbacks: a large current consumption (e.g. 400 μA) in the last transistor P3 in quiescent mode and its capacity to not limit current decrease.

This circuit can be further improved as shown in FIG. 4a, wherein the first preferred embodiment of the invention is shown and consists in a current limiter circuit boosting a non-linear current through a variable load. The comparison between both circuits reveals that the detection and regulation stages are unchanged, the branch N1, R2, D0 is replicated in a branch N4, R3, D1 driven by the same bias voltage and therefore passed through by the same current e.g. 10 μA, the load P1 is changed into a load P5 in series with P4 connected in parallel with a current source CS3 having e.g. 15 μA, the sinking current source CS2 has now a much poorer current sinking capability e.g. 20 μA and the transistor P3 has an aspect ratio W/L substantially smaller than previously e.g. ratio of 1/40. In quiescent mode, the current e.g. 10 μA, which flows through the transistor P5 is sufficiently low for being compensated by the 15 μA that the current source CS3 can provide. Thus, the load of the transistor N4 is formed of the transistor P5 and the current source CS3, the transistor P4 being short-circuited by the latter. It results that the current will be amplified by the current mirror P3, P5 with a current mirror ratio e.g. 1 much lower than the one e.g. 40 of the previous current mirror P1, P3. The sinking current source CS2 e.g. 20 μA will be hence able to compensate the low amplified current and its poor current sinking capability will not disturb the action of the driver circuit 40. When a positive voltage variation dV/dt is detected by the capacitor C, the bias voltage at the gate at the gate terminal GateN increases and there is a non-linear current increase in each one of transistors N1 and N4 with a current peak about 120 μA. The current e.g. 120 μA that flows through the transistor P5 can no longer be compensated by the 15 μA that the current source CS3 can provide. Thus, the latter can now be considered as by-passed by the transistor P4, such that the current mirror P3, P5 is electrically replaced by the current mirror P3, P4+P5 having a current mirror ratio 100 much larger. Thus, the amplified current 100×120 μA=12 mA will largely exceed the current sinking capability of the current source CS2 and will charge the gate of the gate-controlled switching device very rapidly. When a negative voltage variation dV/dt is detected by the capacitor C, the bias voltage at the gate terminal GateN decreases and there is a non-linear current decrease in each one of transistors N1 and N4 which will be mirrored by the current mirror P3, P5. The sinking current source CS2 will compensate totally the mirrored current and, due to its poor current sinking capability, will sink no further current discharging the gate of the gate-controlled switching device. The action of the driver circuit 40 will be not overridden such that such a circuit operates unidirectionally while limiting very fast increase of the current and not preventing very fast decrease of the current.

For better illustrating the performance of the first preferred embodiment of the invention, FIG. 4b shows the simulation results for a current overshoot of 0.3 A during 200 ns (refer to time portion II) with a 20 μA sinking current source CS2, wherein time period I corresponds to the reverse mode of the gate-controlled switching device P0, time period II to the overshoot following the plug-in of a wall plug adapter, time period III to the OFF-state of the gate-controlled switching device P0, time period IV to the bias voltage regulation process and time period V to the forward mode of the gate-controlled switching device P0.

It is noted that the invention such as described according to the first preferred embodiment can be extended to a second preferred embodiment while inverting the polarity of all the components and thus allow the second preferred embodiment to detect and limit large current increase with a negative steep front.

In summary, a circuit configuration for detecting and limiting large current increase based on high current injection at the output terminal out has been described. In particular, a gate-controlled switching device P0, controlled by a driver circuit 40 through a low resistive element R0 and passed through by a current overshoot, will be alternatively driven by the circuit of the present invention while having its control terminal charged by the high injected current. Thus, when large voltage increase generated by a steep front impulse with a positive slope is detected by the capacitor C and transmitted to the gate terminal GateN, the circuit of the present invention bypasses the driver circuit 40 while injecting a significant current peak issued from the transistor P3 towards the gate terminal GateP of the gate-controlled switching device P0, whereas the capacitor C is discharging very slowly through the gate terminal GateN. The current amplification leading to the injected current peak is made through the use of the current mirror P4+P5, P3 with a large current mirror ratio and enhanced by the presence of the diodes D0, D1. In a quiescent mode or when large voltage decrease generated by a steep front impulse with a negative slope is detected by the capacitor C and transmitted to the gate terminal GateN, the transistor P4 becomes short-circuited by the current source CS3 sourcing the current flowing through the diode D1, such that the current mirror P4+P5, P3 is virtually replaced by the current mirror P5, P3 with a much lower current mirror ratio. As a result, the low current of the sinking current source CS2 will be sufficient to sink the lower current mirrored by the current mirror P3, P5 and will then allow the driver circuit 40 to take over the control of the switching device P0. Finally, this circuit configuration operates unidirectional while limiting large current increase but not large current decrease through the gate-controlled switching device P0.

Finally but yet importantly, it is noted that the term “comprises” or “comprising” when used in the specification including the claims is intended to specify the presence of stated features, means, steps or components, but does not exclude the presence or addition of one or more other features, means, steps, components or group thereof. Further, the word “a” or “an” preceding an element in a claim does not exclude the presence of a plurality of such elements. Moreover, any reference sign does not limit the scope of the claims.

1. A variable current amplifier circuit configuration for variably amplifying a current, said variable current amplifier circuit configuration comprising:
an input terminal and an output terminal;
a detection stage, for detecting a voltage variation, said voltage variation being transmitted at a first control terminal of a first transistor which controls a first current, said voltage variation resulting in a current variation of said first current, said detection stage having an input coupled to said input terminal;
a regulation stage, for regulating a bias voltage at said first control terminal and said first current controlled by said bias voltage to a first and second quiescent value respectively, said first quiescent value being a voltage value which is not submitted to said voltage variation and said second quiescent value being a current value which is not submitted to said current variation;
a variable amplification stage, for variably amplifying a second current based on an alternative arrangement of a first current mirror and a second current mirror, wherein:
said first current mirror and second current mirror include at least two transistors,
said second current is a replica of said first current,
said second current mirror has a current mirror ratio much greater than said first current mirror,
said second current, which is amplified by said second current mirror is injected through said output terminal until said first current is regulated to said second quiescent value.

2. A variable current amplifier circuit configuration according to claim 1, wherein said detection stage comprises a capacitive element.

3. A variable current amplifier circuit configuration according to claim 2, wherein said second current is controlled by a second transistor.

4. A variable current amplifier circuit configuration according to claim 3, wherein said first current mirror and second current mirror form a load of said second transistor.

5. A variable current amplifier circuit configuration according to claim 1, wherein said current variation is exponential.

6. A variable current amplifier circuit configuration according to claim 5, wherein each one of said first and second currents flows through a diode.

7. A variable current amplifier circuit configuration according to claim 6, wherein said diode is in series with a resistive element.

8. A variable current amplifier circuit configuration according to claim 1, wherein said first current mirror and second current mirror share a common transistor, the remaining transistors being connected in series.

9. A variable current amplifier circuit configuration according to claim 8, wherein a third current source is connected in parallel with one of said remaining transistors of said second current mirror, said third current source sourcing said second current to be mirrored by said first current mirror.

10. A variable current amplifier circuit configuration according to claim 9, wherein a second current source is connected in series with said common transistor at said output terminal, said second current source having a poor current sinking capability close to said second quiescent value and sinking said second current mirrored by said first current mirror.

11. A variable current amplifier circuit configuration according to claim 1, wherein said transistors are metal oxide semiconductor field effect transistors.

12. A variable current amplifier circuit configuration according to claim 11, wherein said first and second transistors have a polarity different from that of said common transistor and said remaining transistors.

13. A current limiter circuit configuration for limiting current increase, said current limiter circuit configuration comprising at least:
a variable current amplifier circuit configuration as specified in claim 1;
a gate-controlled switching means, said gate-controlled switching means being passed through by a third current and having a first terminal, a second terminal and a second control terminal, wherein said first terminal is connected to said input terminal and said second control terminal is connected to said output terminal;
a driver means, for controlling said gate-controlled switching means through a resistive element, wherein said resistive element has a resistance value small enough so as to not affect an action of said driver means and considered infinite when said second current amplified by said second current mirror is injected through said output terminal, said output current charging said second control terminal for stopping an increase of said third current in response to said voltage variation across said gate-controlled switching means.

14. A current limiter circuit configuration according to claim 13, wherein said gate-controlled switching means is a bi-directional switching means.

15. A current limiter circuit configuration according to claim 13, wherein said gate-controlled switching means is a power metal oxide semiconductor field effect transistor, an insulated gate bipolar transistor, a bipolar junction transistor or any other controllable semiconductor switching device.

16. A current limiter circuit configuration according to claim 15, wherein said gate-controlled switching means has a same polarity as that of said common transistor and said remaining transistors.

17. A battery charging circuit configuration for charging a battery operating in a charge-and-play mode, said battery charging circuit configuration comprising at least:
a current limiter circuit configuration as specified in claim 13, wherein:
a battery will be connected to said second terminal, said battery supplying a device connected to said first terminal,
a power supply means will be then connected to said first terminal for charging said battery, said connected power supply means generating said voltage variation if a voltage difference exists with said battery.

18. A method of detecting and limiting current increase, comprising at least the following steps:
detecting a voltage variation at a first control terminal controlling a first current;
initiating a bias voltage regulation at said first control terminal submitted to said voltage variation to a quiescent value, said quiescent value being a value which is not submitted to said voltage variation;
replicating said first current into a second current;
variably amplifying said second current while mirroring said second current alternatively through a first current mirror or a second current mirror, wherein said second current mirror has a current mirror ratio much greater than said first current mirror;
injecting said second current mirrored by said second current mirror towards an output terminal to which a gate-controlled switching means is connected so as to stop a current increase through said gate-controlled switching means, said injecting step being ended when said bias voltage returns to said quiescent value.
